(19) United States
(12) Patent Application Publication
(10) Pub. No.: US 2007/0238236 A1
(43) Pub. Date: Oct. 11, 2007

(54) Structure and fabrication method of a selectively deposited capping layer on an epitaxially grown source drain

(76) Inventors: Ted Cook JR., Hillsboro, OR (US); Bernhard Sell, Portland, OR (US); Anand Murthy, Portland, OR (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/391,928

(22) Filed: Mar. 28, 2006

(51) Int. Cl. H01L 21/8234; H01L 21/336

(52) U.S. Cl. 438/197

(57) ABSTRACT

A method and apparatus to improve the contact formation of salicide and reduce the external resistance of a transistor is disclosed. A gate electrode is formed on a surface of a substrate. A source region and a drain region are isotropically etched in the substrate. A Silicon Germanium alloy is doped in situ with Boron in the source region and in the drain region. Silicon is deposited on the Silicon Germanium alloy. Nickel is deposited on the Silicon. A Nickel Silicon Germanium silicide layer is formed on the Silicon Germanium alloy. A Nickel Silicon silicide layer is formed on the Nickel Silicon Germanium silicide layer.

### TECHNICAL FIELD

This invention relates to the field of semiconductor integrated circuits, and, in particular, to forming a MOS transistor.

### BACKGROUND

Integrated circuits are usually manufactured in and on silicon and other semiconductor substrates. An integrated circuit may include millions of interconnected transistors that are formed over an area of a few square centimeters.

Such a transistor usually includes a gate dielectric layer on the silicon substrate, a gate electrode on the gate dielectric layer, and source and drain regions in the silicon substrate on opposite sides of the gate electrode. The source and drain regions are usually made by implanting dopant impurities into the silicon substrate.

To increase electron mobility and cost-effectiveness, Silicon Germanium has been used as a material for the source and drain regions. Germanium has a 4.2% larger lattice constant (e.g., atomic spacing) than Silicon. Silicon Germanium also has a larger lattice constant, the extent of which depends on the percentage composition of Germanium. When Silicon is grown on Silicon Germanium, under proper conditions the Silicon lattice stretches to match that of the Silicon Germanium at the Silicon/Silicon Germanium interface. When silicon germanium is grown on Silicon, under proper conditions the Silicon Germanium lattice gets compressed. For each method, there is critical thickness of the grown layer (be it silicon or silicon germanium) past which the grown layer relaxes as lattice defects propagate.

Silicon Germanium offers improved speed characteristics for transistors comprised thereof because compared to elemental silicon, Germanium has a lower electron effective mass and lower hole effective mass (leading to higher electron mobility and higher hole mobility). Silicon Germanium compounds benefit from the increased mobilities of the constituent germanium. Further, the silicon germanium creates an anisotropic structure that alters the conduction and valence bands of the materials. When combined with other semiconductor layers (e.g., heterolayers) with different band gaps, conduction band and valence band discontinuities can be designed to create quantum wells or built-in electric fields to accelerate carriers across the heterolayers.

The amount of Germanium in the epitaxial SiGe layer is chosen based on transistor performance requirements (typically, between 15% and 30%). This amount of Germanium may not be optimum for either contact resistance between salicide and source drain, nor for uniform salicide formation resulting in reduced yield and performance.

### BRIEF DESCRIPTION OF THE DRAWINGS

The present invention is illustrated by way of example, and not by way of limitation, in the figures of the accompanying drawings.

FIG. 1 is an illustration of a cross-sectional side view of adjacent transistors in accordance with one embodiment;

FIG. 2 is an illustration of a cross-sectional side view showing the formation of recesses in the substrate of FIG. 1;

FIG. 3 is an illustration of a cross-sectional side view showing the formation of a silicon germanium alloy in the recesses of the substrate of FIG. 2.

FIG. 4 is an illustration of a cross-sectional side view showing the deposit of silicon on the silicon germanium alloy of the substrate of FIG. 3 in accordance with one embodiment.

FIG. 5 is a cross-sectional side view showing the removal of the mask on the substrate of FIG. 4 in accordance with one embodiment.

FIG. 6 is an illustration of a cross-sectional side view showing the deposition of a metal on the substrate of FIG. 5 in accordance with one embodiment.

FIG. 7 is an illustration of a cross-sectional side view of a transistor after the reaction of the metal in FIG. 6 in accordance with one embodiment.

FIG. 8 is an illustration of a cross-sectional side view showing the removal of the mask on the substrate of FIG. 3 in accordance with another embodiment.

FIG. 9 is an illustration of a cross-sectional side view showing the deposition of silicon on the substrate of FIG. 8 in accordance with another embodiment.

FIG. 10 is an illustration of a cross-sectional side view showing the deposition of a metal on the substrate of FIG. 9 in accordance with another embodiment

FIG. 11 is an illustration of a cross-sectional side view of a transistor after the reaction of the metal in FIG. 10 in accordance with another embodiment.

FIG. 12 is a flow diagram illustrating a method for fabricating the transistor of FIG. 7 and FIG. 11 in accordance with one embodiment.

### DETAILED DESCRIPTION

The following description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the spirit and scope of the present invention.

An embodiment of the invention reduces the external resistance of a transistor by utilizing a silicon germanium alloy for the source and drain regions, a metal silicon germanium silicide layer, and a metal silicon silicide layer to form the contact surface of the source and drain regions. The metal may be, for example, Nickel. The interface between the silicon germanium and the nickel silicon germanium silicide has a lower specific contact resistivity based on a decreased metal-semiconductor work function between the silicon germanium and the nickel silicon germanium silicide and an increased carrier mobility in silicon germanium versus silicon. The nickel silicon silicide provides for a better contact formation. The silicon germanium may be doped to further tune its electrical properties. A reduction of the external resistance of a transistor equates to increased transistor performance both in switching speed and power consumption.

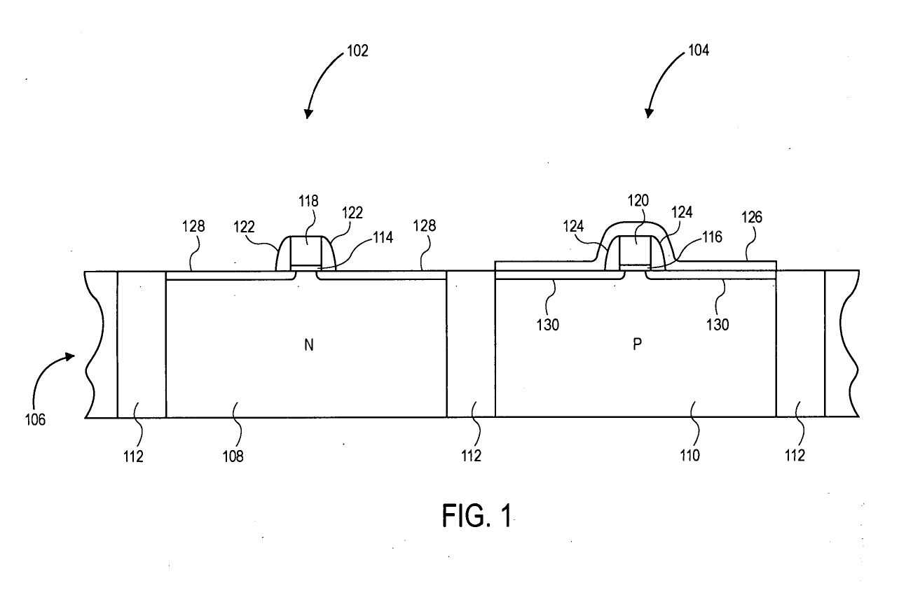

FIG. 1 illustrates one embodiment of the manufacture of two adjacent transistors 102, 104 on a silicon substrate 106. Transistor 102 is a metal-oxide semiconductor (MOS) transistor that is made on a p-type substrate or well. Transistor 104 is a metal-oxide semiconductor (MOS) transistor that is made on an n-type substrate or well.

The partially-manufactured transistors 102, 104 shown in FIG. 1 are manufactured according to a conventional process. P-type dopants are implanted into the left portion of the silicon substrate 106 to form a P-well 108. N-type dopants are implanted into the right portion of the silicon substrate 106 to form an N-well 110. P-well 108 is separated from N-well 110 by an isolation region such as a silicon dioxide shallow trench isolation (STI) region 112 or also referred to as an isolation wall.

Gate dielectric layers 114, 116 are subsequently grown on P-well 108 and N-well 110, respectively. Gate dielectric layers 114, 116 may be made from well know material such as silicon dioxide or nitrided silicon dioxide. In one embodiment, the gate dielectric layers 114 and 116 may have a thickness of less than about 40 Å. A gate electrode may be formed on the gate dielectric layers. For example, polysilicon gate electrodes 118, 120 are formed on gate dielectric layers 114, 116, respectively. Polysilicon gate electrode 118 may be doped with an N-type dopant such as phosphorous or arsenic. Polysilicon gate electrode 120 may be doped with a P-type dopant such as boron.

Source Drain extensions 128 and 130 may be formed on opposite sides of polysicon gate electrodes 118 and 120, respectively. Vertical sidewall spacers 122 and 124 may also be formed on opposite sides of polysilicon gate electrodes 118 and 120, respectively. In accordance with one embodiment, the vertical sidewall spacers 122 and 124 may be formed of SiO₂ or SiBN₁₄.

A mask 126 may be formed on transistor 104. More specifically, the mask 126 is deposited on polysilicon gate electrode 120, vertical sidewall spacers 124, and the remaining exposed surface of the N-well 110. In accordance with one embodiment, the mask 126 may act as a blocking layer to further processing steps.

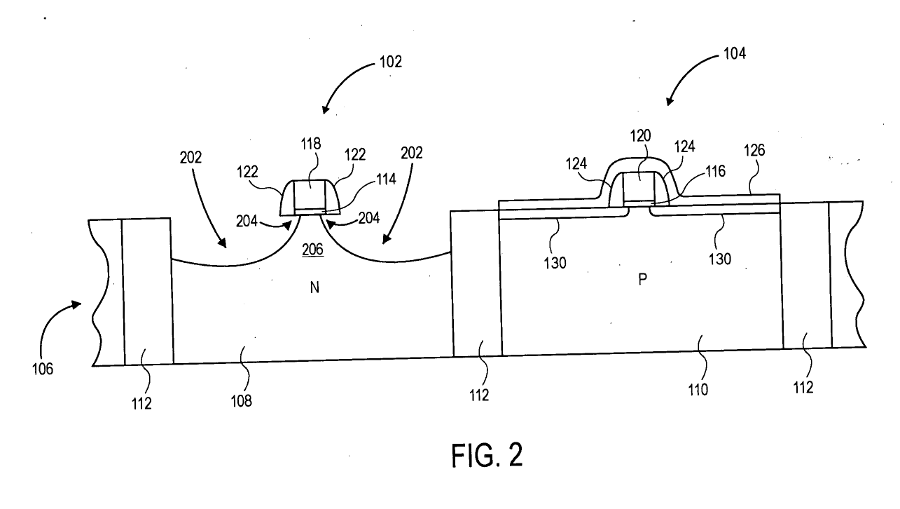

As illustrated in FIG. 2, recesses 202 are subsequently etched into an upper surface of P-well 108. An isotropic etchant may be used to selectively remove the S/D extensions 118, 120 and exposed silicon between the trench isolation region 112, gate dielectric layer 114, and sidewall spacers 122. Etching is continued until tip portions 204 of recesses 202 are formed below gate dielectric layer 114. As such, source and drain recesses 202 are formed on opposite sides and below polysilicon gate electrode 118. Each one of the source and drain recesses 202 has a respective tip portion 204 below the polysilicon gate electrode 118. A channel region 206 is defined between the tip portions 204. The mask 126 of transistor 104 temporarily prevents further process to the transistor 104.

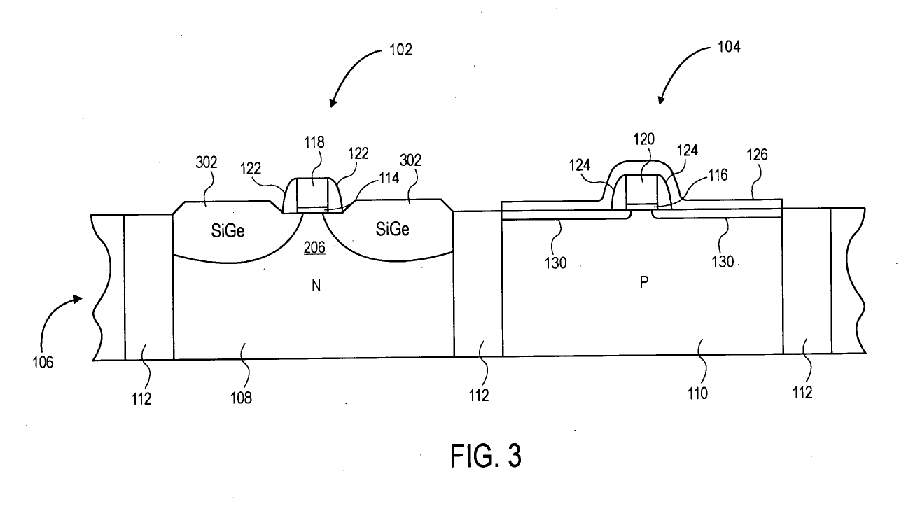

FIG. 3 illustrates the structure of FIG. 2 after the formation of source and drain regions. Source and drain regions may be formed by epitaxially growing silicon germanium within recesses 202 to form a silicon germanium layer 302. It should be noted that silicon germanium grows selectively on the material of silicon substrate 106, as opposed to the materials of shallow trench isolation region 112, gate dielectric layers 114, sidewall spacers 122, and mask 126. The silicon germanium crystal does not grow on the SiO2 or Si3N4 dielectric layer. Those of ordinary skills in the art will recognize that there exist many wells known techniques for deposition of the silicon germanium. For example, on deposition technique may include reduced pressure chemical vapor deposition (“CVD”) epitaxial deposition. Other deposition techniques include atmospheric CVD epitaxy and ultra high vacuum CVD epitaxy. Each deposition technique is a specific form of vapor phase epitaxy as the deposited silicon germanium layer 302 is formed of a single crystal. In one embodiment, the silicon germanium alloy may include a germanium composition between about 5% to about 50%.

In accordance with one embodiment, the silicon germanium deposition method includes CVD epitaxy. The epitaxy may occur between 600° C. and 800° C. at a pressure between 10 and 760 Torr. Either H₂, N₂ or He can be used as a carrier gas. The silicon source precursor gas can be SiH₂Cl₂, SiH₄, or Si₂H₆. In one embodiment, GeH₄ is the germanium source precursor gas. HCl or Cl₂ may be added as an etching agent to increase the material selectivity of the deposition. In one embodiment, the resulting silicon germanium layer 302 may be deposited in recesses 202 to form source and drain regions. The layer of silicon germanium 302 may have a thickness between about 500 and about 2000 Angstroms. FIG. 3 illustrates an embodiment where the deposited silicon germanium layer 302 extends above a top surface of substrate 106. The silicon germanium layer 302 is formed both above and below a top surface of substrate 106. By forming silicon germanium layer 302 above the top surface of the substrate 106, a raised Source Drain region is formed, increasing conductivity. The increased conductivity in turn improves device performance. In another embodiment, the silicon germanium layer 302 may have a thickness between about 200 and about 1000 Angstroms.

The silicon germanium layer 302 can be doped to adjust its electrical and chemical properties. The doping can occur using a variety of dopants and with a variety of doping techniques. For example, silicon germanium can be in situ doped with p-type impurities, such as boron, to a dopant concentration level between 1×10¹⁸/cm³ and 3×10²¹/cm³ with a concentration of approximately 1×10²⁰/cm³ being preferred. In an embodiment for manufacturing a PMOS device, silicon germanium is doped with boron in situ during epitaxy by utilizing the precursors noted above and an additional B₂H₆ precursor gas as the source of the boron dopant during the silicon germanium epitaxial deposition. The benefit of doping silicon germanium in situ is that the shape of recesses 202 makes it very difficult to dope silicon germanium after it has been deposited in area shadowed by sidewall spacers 122. Those of ordinary skills in the art will recognize that other techniques may also be used to dope the silicon germanium layer 302.

In an embodiment, a fraction of the boron dopant added during the silicon germanium deposition is not activated at this time. That is, after deposition, boron atoms are in the silicon germanium layer 302 but have not yet substituted into silicon sites in the lattice where they can provide a hole (i.e., a lack of an electron). In an embodiment, the thermal activation of the dopant is deferred until subsequent processing steps (such as the silicide anneal), reducing the thermal budget and resulting dopant diffusion to enable a very abrupt source/drain junction to be formed, improving device performance.

As introduced, the deposited silicon germanium has a larger lattice constant, the magnitude of which depends on the atomic percent germanium in the silicon germanium alloy. When deposited on the silicon substrate 106, the lattice of the silicon germanium is compressed to accommodate crystalline growth. The compression in the silicon germanium layer 302 forming source and drain regions further creates compression in the silicon substrate 106 region located between the silicon germanium source and drain regions and beneath the gate dielectric layer 114 (i.e., channel 206 of transistor 102). The compression creates an anisotropic atomic structure in the channel region, altering the conduction and valence bands of the channel material. The compressive stress further reduces the hole effective mass in the channel area of silicon substrate 106, in turn increasing hole mobility. The increased hole mobility increases the saturation channel current of the resulting MOS transistor, thereby improving the device performance.

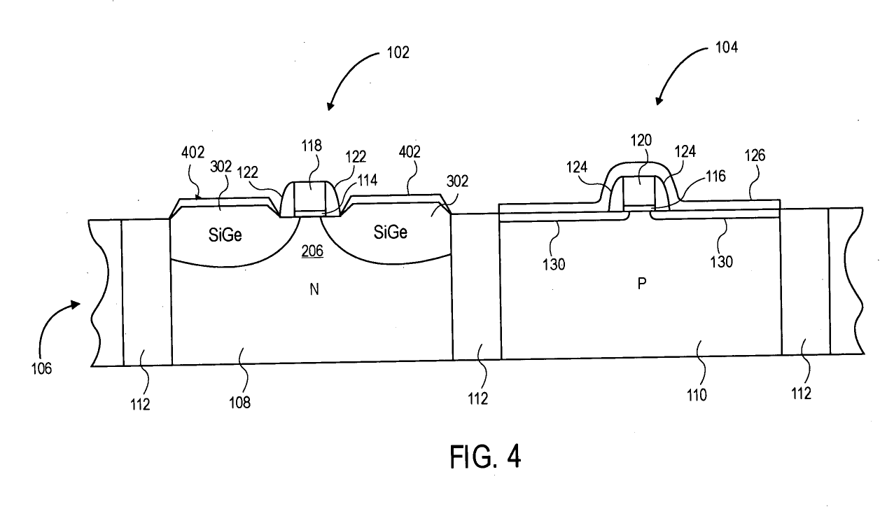

FIG. 4 illustrates the structure of FIG. 3 after the deposition of a sacrificial layer in accordance with one embodiment. In one embodiment, the sacrificial layer includes a thin layer of silicon 402 that is selectively deposited on the exposed surface of the silicon germanium layer 302. It should be noted that silicon grows selectively on the material of silicon germanium layer 302, as opposed to the materials of shallow trench isolation region 112, gate dielectric layers 114, sidewall spacers 122, and hard masks 126. The silicon layer 402 does not grow on the SiO₂ or Si₃N₄ dielectric layer. The thickness of the layer of silicon 402 may range from 200 A to 400 A depending on the type and thickness of the metal to be deposited on the layer of silicon 402. In one embodiment, the deposition technique may include reduced pressure chemical vapor deposition (“CVD”) epitaxial deposition. In other embodiments, the deposition technique includes atmospheric CVD epitaxy and ultra high vacuum CVD epitaxy. Each deposition technique is a specific form of vapor phase epitaxy as the deposited silicon layer 402 is formed of a single crystal. In another embodiment, the sacrificial layer includes silicon germanium having a germanium composition that is less than the germanium in the silicon germanium layer. For example, the sacrificial layer may include silicon germanium with a germanium composition of up to about 30%.

The deposition process may include routing gases to the vents for two reasons: (1) to stabilize DCS and HCL flows at desired set points; (2) to allow temperature to ramp to a desired temperature (between 777° C. an 825° C.).

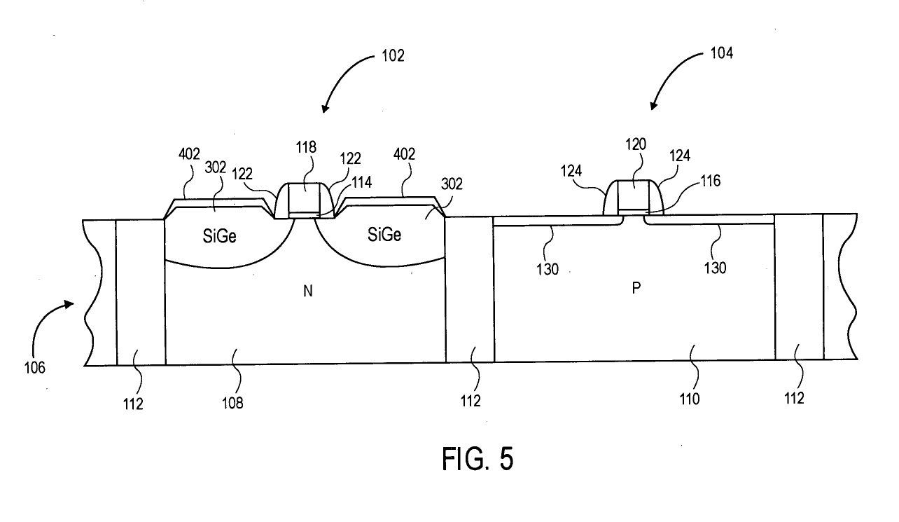

FIG. 5 illustrates the structure of FIG. 4 after the removal of the mask 126 from transistor 104 in accordance with one embodiment. The mask 126 is removed to leave the structure of transistor 104 exposed as illustrated in FIG. 5. In particular, the exposed components of transistor 104 include the source drain regions 130, sidewall spacers 124, and gate electrode 120. The exposed components of transistor 102 include silicon layer 402, sidewall spacers 122, and gate electrode 118.

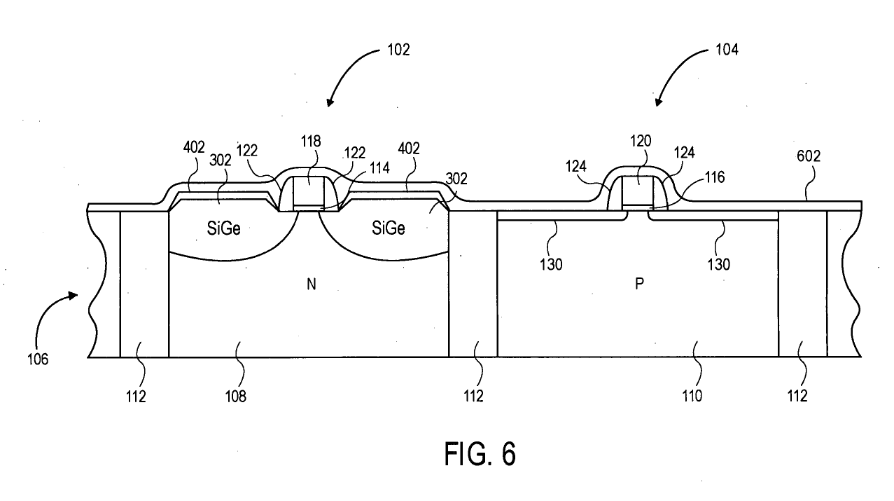

FIG. 6 illustrates the structure of FIG. 5 after deposition of a metal. A metal 602, such as Nickel, is deposited on both transistors 102 and 104. Those of ordinary skills in the art will recognize that there are many ways to deposit the metal 602. One example of a deposition technique includes standard sputtering techniques (i.e., physical vapor deposition or “PVD”). The metal 602 reacts with certain components of transistors 102 and 104. Metal 602 that has not reacted with the components of transistors 102 and 104 is subsequently removed.

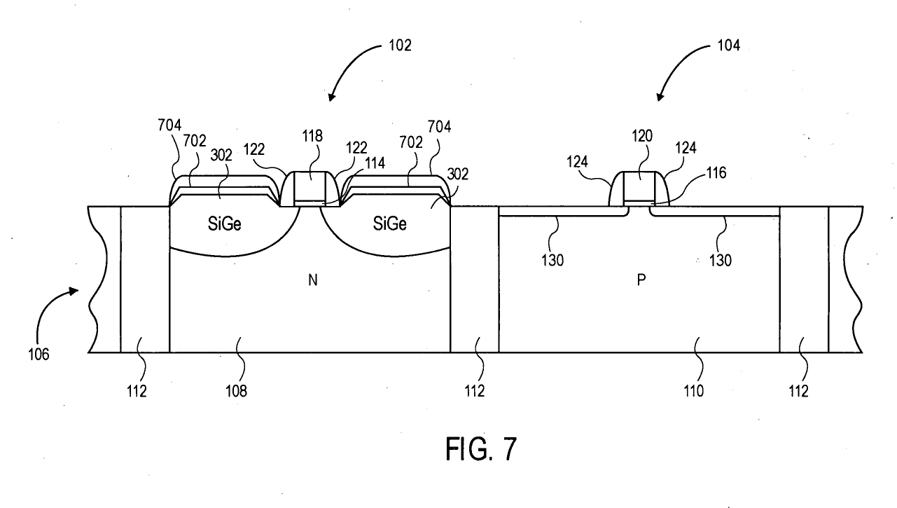

FIG. 7 illustrates a cross-sectional side view of a transistor after the reaction of the metal with transistors 102 and 104 in FIG. 6 in accordance with one embodiment. FIG. 7 also illustrates the formation of self-aligned silicide layers 702 and 704. One skilled in the art will recognize that a silicide layer is formed by depositing a thin layer of refractory metal.

Refractory metals include, among others, cobalt, titanium and nickel. In an embodiment, the refractory metal is nickel. The selection of a refractory metal requires consideration of not only electrical compatibility, but also mechanical and chemical compatibility with the underlying silicon germanium layer 302 occupying the source and drain regions and the exposed source and drain regions of the corresponding NMOS devices on the same substrate. For example, the silicide layer must be continuous and uniform to aid reducing interface resistance between the silicide layer and the underlying silicon germanium layer 302. Nickel tends to react uniformly with both silicon and germanium, forming a stable ternary Ni(SiGe) phase whereas cobalt and titanium react preferentially with silicon and segregate the germanium component of the silicon germanium alloy 302. Further, the titanium and cobalt based silicon germanium silicide have reduced thermal stability compared to nickel silicon germanium silicide. Improper refractory metal selection creates a non-ideal interface between the silicide and semiconductor that increases the interface resistance independent of otherwise electrically compatible materials.

FIG. 7 illustrates an embodiment where the refractory metal is PVD nickel. Environmentally, the PVD nickel deposition occurs between 20° C. and 200° C. and at a pressure less than 50 millitorr. The thickness of the nickel may be between 50 and 200 angstroms. The nickel deposition is followed by a rapid formation anneal at between 325° C. and 450° C. for less than or equal to 60 seconds using, for example, rapid thermal anneal (“RTA”) equipment. During the formation anneal, the Nickel layer 602 atop the silicon layer 402 reacts to form a first layer of Nickel Silicon Germanium silicide 702 and a second layer of Nickel Silicon Silicide 704 as illustrated in FIG. 7. In one embodiment, the deposited Nickel 602 may have a thickness between about 200 and 400 Angstroms. As the nickel 602 is deposited over the entire exposed surface of the silicon substrate 106, the unreacted nickel (i.e., the nickel that has not reacted with silicon or silicon germanium to form a silicide with its underlying layer as it is deposited atop sidewall spacers 122 or isolation regions 112) is removed using a wet etch chemistry of, for example, a mixture of hot H₂O₂ and hot H₂SO₄. The remaining reacted nickel atop the silicon germanium layer 302 (source and drain regions) and the gate 118 regions then undergoes a final anneal between 400° C. and 550° C. to complete the nickel silicon germanium silicide 702 and the nickel silicon silicide 704 formation as shown in FIG. 7. The silicide layers 702 and 704 may be further capped with, for example, a titanium nitride cap (not shown) to prevent the nickel silicon germanium silicide layer 702 and the nickel silicon silicide layer 704 from oxidizing during subsequent processing steps as is well known in the art. In one embodiment, each silicide layer may have a thickness between 200 and 400 Angstroms.

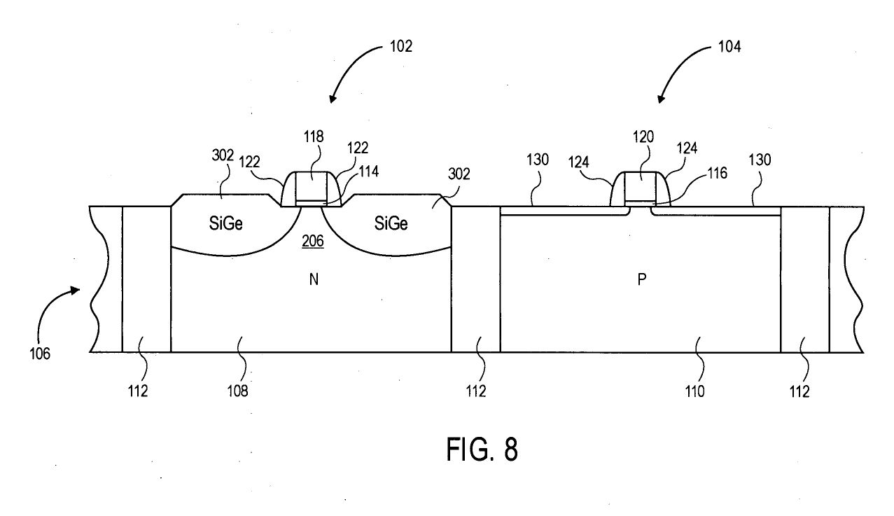

FIG. 8 illustrates the structure of FIG. 3 after the removal of the mask 126 from transistor 104 in accordance with another embodiment. The mask 126 is subsequently removed to leave the structure of transistor 104 exposed as illustrated in FIG. 8. In particular, the exposed components of transistor 104 include Source Drain regions 130, sidewall spacers 124, and gate electrode 120.

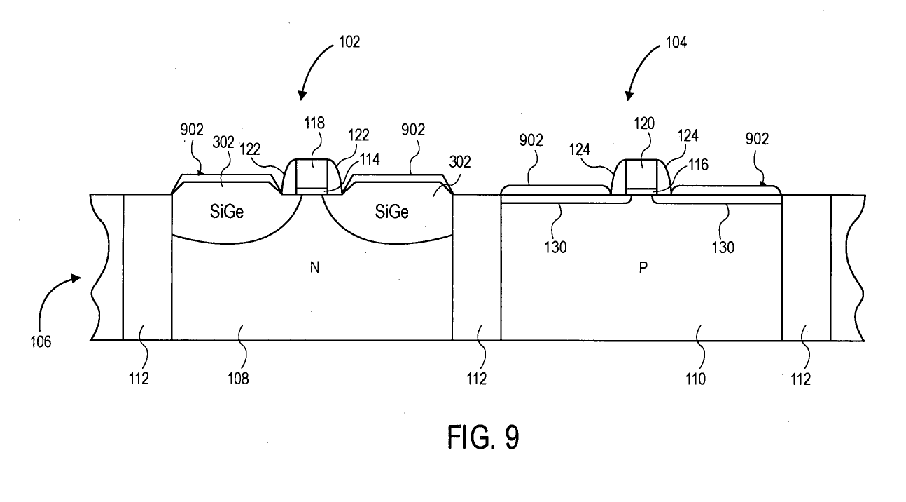

FIG. 9 illustrates the structure of FIG. 8 after the deposition of a sacrificial layer in accordance with one embodiment. The sacrificial layer may include for example, silicon. A thin layer of silicon 902 is selectively deposited on the exposed surface of the silicon germanium layer 302 of the transistor 106. A thin layer of silicon 902 is deposited on the exposed surface of the Source Drain regions 130 of the transistor 104. The thickness of the layer of silicon 902 may range from 200 A to 400 A depending on the type and thickness of the metal to be deposited on the layer of silicon 902. The deposition process of the silicon 902 layer was previously described with respect to FIG. 4.

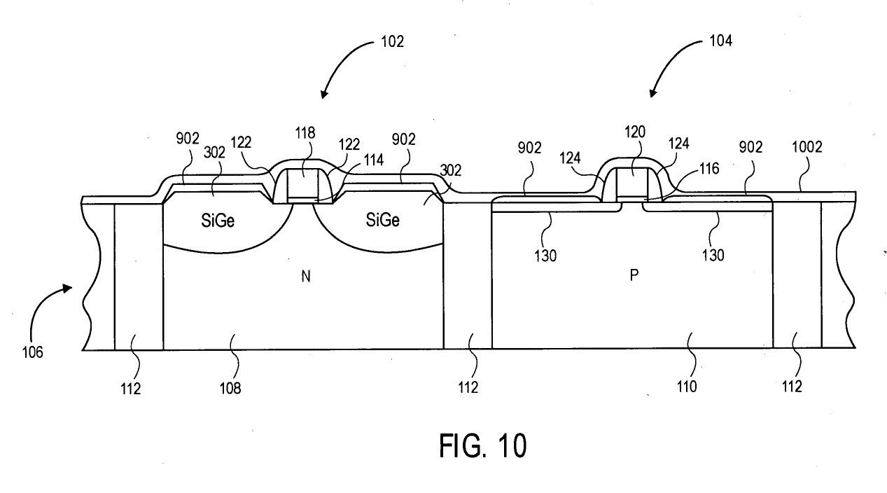

FIG. 10 illustrates the structure of FIG. 9 after the deposition of a metal 1002, such as nickel. The deposition process of the metal layer 1002 was previously described with respect to FIG. 6.

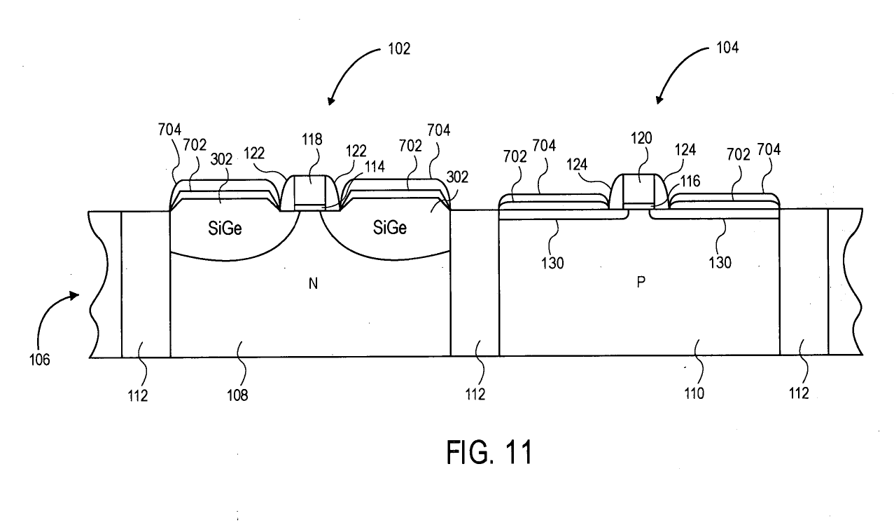

FIG. 11 illustrates the structure of FIG. 10 after the metal has reacted with the transistors 102 and 104. The reaction process was previously described with respect to FIG. 7.

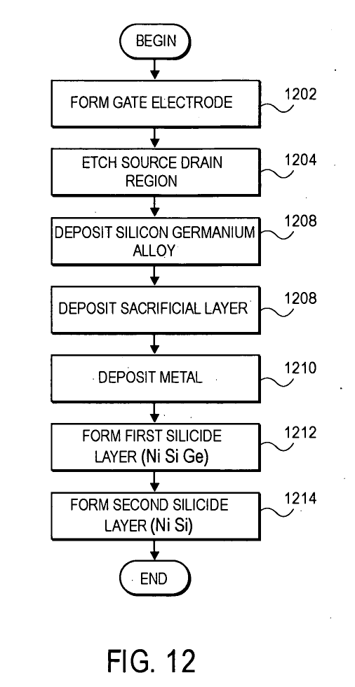

FIG. 12 is a flow diagram illustrating a method for fabricating the transistor of FIGS. 7 and 11. At 1202, a gate electrode is formed as illustrated in FIG. 1. At 1204, source and drain regions are etched in the substrate as illustrated in FIG. 2. At 1206, a silicon germanium alloy is deposited in the source and drain regions as illustrated in FIG. 3. At 1208, a sacrificial layer of a material is deposited on the silicon germanium alloy as illustrated in FIGS. 4 and 9. In one embodiment, the sacrificial layer includes silicon. At 1210, a metal, such as Nickel, is deposited on the sacrificial layer as illustrated in FIGS. 6 and 10. The contacts between the metal and the sacrificial layer and the silicon germanium alloy form two layers of silicide. At 1212, the metal reacts with the silicon germanium to form a first layer of silicide. In one embodiment, the first layer of silicide includes Nickel Silicon Germanium silicide formed by Nickel reacting with Silicon Germanium. At 1214, the metal reacts with the sacrificial layer to form a second layer of silicide. In one embodiment, the second layer of silicide includes Nickel Silicon silicide formed by Nickel reacting with Silicon.

Although the operations of the method(s) herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. A method comprising:
forming a gate electrode on a surface of a substrate;
isotropically etching a source region and a drain region in the substrate;
depositing a Silicon Germanium alloy in the source region and in the drain region;
depositing on the Silicon Germanium alloy, a sacrificial layer of a material having a Germanium concentration lower than the Germanium concentration of the Silicon Germanium alloy;
depositing a metal on the sacrificial layer;
forming a first silicide layer on the Silicon Germanium alloy; and
forming a second silicide layer on the first silicide layer.

2. The method of claim 1 further comprising doping the Silicon Germanium alloy in situ with Boron.

3. The method of claim 1 wherein the Silicon Germanium alloy has a top surface that is above a plane defined by the surface of the substrate.

4. The method of claim 1 wherein the Silicon Germanium alloy has a Germanium composition between about 5% and about 50%.

5. The method of claim 1 wherein the Silicon Germanium alloy has a thickness between about 200 and about 1000 Angstroms.

6. The method of claim 1 wherein the sacrificial layer includes Silicon.

7. The method of claim 6 wherein the Silicon has a thickness between about 200 and about 400 Angstroms.

8. The method of claim 1 wherein the sacrificial layer includes Silicon Germanium with a Germanium composition up to 30%.

9. The method of claim 1 wherein the metal includes Nickel.

10. The method of claim 9, wherein the Nickel has a thickness between about 200 and about 400 Angstroms.

11. The method of claim 9 wherein the first silicide layer includes a Nickel Silicon Germanium silicide.

12. The method of claim 11 wherein the Nickel Silicon Germanium silicide has a thickness between about 200 and about 400 Angstroms.

13. The method of claim 9 wherein the second silicide layer includes a Nickel Silicon silicide.

14. The method of claim 13 wherein the Nickel Silicon silicide has a thickness between about 200 and about 400 Angstroms.

15. A method comprising:
forming a gate electrode on a surface of a substrate;
isotropically etching a source region and a drain region in the substrate;
depositing a Silicon Germanium alloy in the source region and in the drain region;
doping the Silicon Germanium alloy in situ with Boron;
depositing Silicon on the Silicon Germanium alloy;
depositing Nickel on the Silicon; and
forming a Nickel Silicon silicide layer on the Silicon Germanium alloy; and
forming a Nickel Silicon Germanium silicide layer on the Nickel Silicon silicide layer.

16. The method of claim 15 wherein the Silicon Germanium alloy has a top surface that is above a plane defined by the surface of the substrate.

17. A transistor comprising:
a substrate of silicon having a channel region with first dopant impurities to have a first conductivity type;
a gate dielectric layer on the channel region;
a conductive gate electrode on the gate dielectric layer;
source and drain regions on opposite sides of the channel region, the source and drain regions being made of a Silicon Germanium alloy;
a Nickel Silicon silicide layer formed on the Silicon Germanium alloy;
a Nickel Silicon Germanium silicide layer formed on the Nickel Silicon silicide layer.

18. The transistor of claim 17 wherein the Silicon Germanium alloy is doped in situ with Boron.

19. The transistor of claim 17 wherein the Silicon Germanium alloy has a top surface that is above a plane defined by the surface of the substrate.

20. The transistor of claim 17 wherein the Silicon Germanium alloy has a germanium composition between 5% and 50%.
